(19) United States
(12) Patent Application Publication
(10) Pub. No.: US 2009/0008698 A1
(43) Pub. Date: Jan. 8, 2009

(54) NONVOLATILE MEMORY DEVICE AND METHOD FOR FABRICATING THE SAM

(75) Inventors: Seung-Cheol LEE, Ichon-shi (KR); Chul-Sik JANG, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/965,454

(22) Filed: Dec. 27, 2007

(30) Foreign Application Priority Data
Jul. 2, 2007 (KR) 10-2007-0066169

(51) Int. Cl. H01L 29/792; H01L 29/788; H01L 21/336

(52) U.S. Cl. 257/321; 257/324; 438/264; 438/287; 257/E21.422; 257/E21.423; 257/E29.3; 257/E29.309

(57) ABSTRACT

A nonvolatile memory device includes an active region which is defined by an isolation layer formed in a substrate and has a recess therein in a channel width direction, wherein an upper portion of the active region having the recess projects over an upper portion of the isolation layer, a lower insulation layer formed along a surface of the active region and a top surface of the isolation layer, a charge storage layer formed over the lower insulation layer, an upper insulation layer formed over the charge storage layer, and a gate electrode formed over the upper insulation layer.

### CROSS-REFERENCE TO RELATED APPLICATIONS

The present invention claims priority to Korean patent application number 2007-0066169, filed on Jul. 2, 2007, which is incorporated by reference in its entirety.

### BACKGROUND OF THE INVENTION

The present invention relates to a nonvolatile memory device and a method for fabricating the same, and more particularly, to a unit cell in a nonvolatile memory device including a multi-channel for storing data and a method for fabricating the same.

Recently, there has been increased demand for nonvolatile memory devices which can be electrically programmed and erased and do not perform a refresh operation for periodically re-writing data unlike a volatile memory device, thereby achieving low power consumption. To develop a mass storage memory device, research is in progress for fabricating a highly integrated nonvolatile memory device.

Demand for a flash memory device which belongs to the nonvolatile memory devices has been increased. Each of memory cells in the flash memory device includes a gate having a horizontal channel, i.e., a channel formed in a horizontal direction on a plane. When the gate has the horizontal channel, convenience of the fabrication is secured. However, it can not actually cope with the decrease of a design rule of the device.

For instance, among the flash memory devices, a NAND flash memory device has a plurality of memory cells connected in series, forming a unit string. Thus, the NAND memory device is highly integrated to a certain degree. However, a memory device fabricated by a process technology of 40 nm or less has problems such as an interference and a disturbance, i.e., a phenomenon that a threshold voltage of a neighboring cell changes during program operation of a cell, and thus it is difficult to fabricate the memory device by a process technology under 40 nm.

In order to minimize the interference and the disturbance in the highly integrated memory device, a final inspection critical dimension (FICD) of a memory cell gate should be reduced as much as possible. However, when the CD of the gate is reduced, a short channel effect (SCE) and a drain induced barrier lowering (DIBL) effect are generated. Also, as the CD decreases, an operation current decreases so that an operation speed decreases during program and erasure operations, and a coupling ratio, which is a ratio of capacitance of a dielectric layer in a unit memory cell to entire capacitance of the unit memory cell, decreases.

### SUMMARY OF THE INVENTION

To overcome the above-mentioned problems, this invention provides a nonvolatile memory device and a method for fabricating the same by increasing an effective channel width to cope with decrease of a gate area due to the high integration of the memory device, thereby securing an operation current.

In accordance with a first aspect of the present invention, there is provided a nonvolatile memory device. The device includes an active region which is defined by an isolation layer formed in a substrate and has a recess therein in a channel width direction wherein an upper portion of the active region having the recess projects over an upper portion of the isolation layer, a lower insulation layer formed along a surface of the active region and a top surface of the isolation layer, a charge storage layer formed over the lower insulation layer, an upper insulation layer formed over the charge storage layer, and a gate electrode formed over the upper insulation layer.

In accordance with a second aspect of the present invention, there is provided a nonvolatile memory device. The device includes an active region which is defined by an isolation layer formed in a substrate and has a recess therein in a channel width direction wherein an upper portion of the active region having the recess projects over an upper portion of the isolation layer, a tunneling insulation layer formed along a surface of the active region and a top surface of the isolation layer, a floating gate formed over the tunneling insulation layer, a dielectric layer formed over the floating gate, and a control gate formed over the dielectric layer.

In accordance with a third aspect of the present invention, there is provided a method for fabricating a nonvolatile memory device. The method includes forming an isolation layer to define an active region in a substrate, forming a recess in the active region, exposing inner and outer walls of the active region by removing a portion of the isolation layer, forming a lower insulation layer along a surface of the active region and a top surface of the isolation layer, forming a charge storage layer over the lower insulation layer, forming an upper insulation layer over the charge storage layer, and forming a gate electrode over the upper insulation layer.

In accordance with a fourth aspect of the present invention, there is provided a method for fabricating a nonvolatile memory device. The method includes forming an isolation layer to define an active region in a substrate, forming a recess in the active region, exposing inner and outer walls of the active region by removing a portion of the isolation layer, forming a tunneling insulation layer along a surface of the active region and a top surface of the isolation layer, forming a floating gate over the tunneling insulation layer, forming a dielectric layer over the floating gate, and forming a control gate over the dielectric layer.

### BRIEF DESCRIPTION OF THE DRAWINGS

FIG. 1 is a perspective view of a nonvolatile memory device in accordance with the present invention.

FIG. 2A is a cross-sectional view figured along a first dotted line I-I′ in FIG. 1.

FIG. 2B is a cross-sectional view figured along a second dotted line II-II′ in FIG. 1.

FIGS. 3A to 3N are perspective views of a method for fabricating the nonvolatile memory device in FIG. 1.

### DESCRIPTION OF SPECIFIC EMBODIMENTS

Embodiments of the present invention relate to a method for a nonvolatile memory device and a method for fabricating the same.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the second layer or the substrate. Furthermore, the same or like reference numerals throughout the various embodiments of the present invention represent the same or similar elements in different drawings.

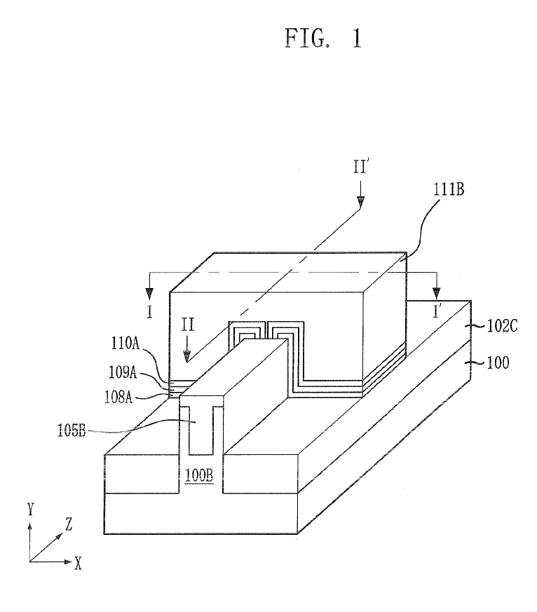

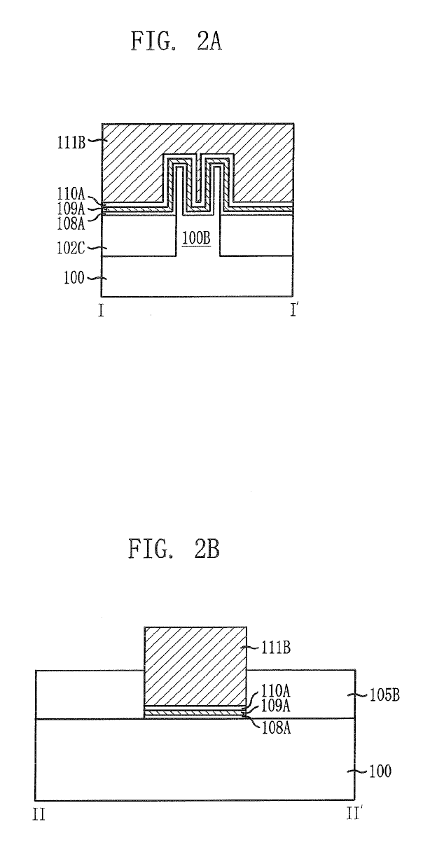

FIG. 1 is a perspective view of a floating trap type memory device, i.e., a memory device for storing an electric charge in an insulating charge storage layer formed between a gate electrode and a substrate, illustrating a nonvolatile memory device in accordance with an embodiment of the present invention. FIG. 2A is a cross-sectional view figured along a first dotted line I-I′ in FIG. 1. FIG. 2B is a cross-sectional view figured along a second dotted line II-II′ in FIG. 1. For the explanation, the description will be followed focusing on a gate electrode of a memory cell which determines a channel width.

Referring to FIGS. 1 to 2B, the nonvolatile memory device of the present invention includes an active region 100B having a recess in a channel width direction, i.e., an X axis. Although a ‘U’ type having a recess is figured in this embodiment for the facility of the description, a ‘W’ type having two recesses may be formed. That is, the number of the recesses is not limited can be chosen appropriately according to a line width of the active region 100B in consideration of a fabrication process, i.e., a mask process including a photo-exposure process.

The active region 100B is defined by an isolation layer 102C in a substrate 100 as a line type or an island type extending in a channel length direction, i.e., a Z axis direction. When the active region 100B is defined as the line type, it corresponds to a NAND flash memory device having memory cells connected in series. When the active region 100B is defined as the island type, it corresponds to a NOR flash memory device. A top surface of the isolation layer 102C is lowered to the level of a bottom of the recess. The top surface of the isolation layer 102C can be higher or lower than the bottom of the recess and varies according to a target channel dimension. Thus, the recess projects with respect to an upper portion of the isolation layer 102C so that sidewalls of the recess, i.e., sidewalls formed in the channel width direction, also project to be exposed. In short, a bottom portion and inner and outer sidewalls of the recess function as a channel region, thereby forming a multi-channel.

The active region 100B is formed either in the semiconductor substrate 100 as a single body or in a separate semiconductor layer (not shown) as a single body formed over the substrate 100. The semiconductor substrate 100 or the separate semiconductor layer may be of silicon (Si) or an alloy of silicon and germanium (SiGe). The semiconductor substrate 100 or the separate semiconductor layer may be a bulk substrate or a silicon-on-insulator (SOI) substrate.

In this embodiment, the nonvolatile memory device includes a lower insulation layer 108A, a charge storage layer 109A, and an upper insulation layer 110A stacked sequentially in a perpendicular direction of the channel width along the active region 100B. The above three layers are formed along a surface having a height difference formed by the recess in the active region 100B.

The lower insulation layer 108A and the upper insulation layer 110A may be an oxide layer, e.g., a silicon oxide (SiO₂) layer or a high-k film having a dielectric coefficient higher than that of the SiO₂ layer, i.e., higher than approximately 3.9, which is made of one of metal oxide-based materials such as hafnium oxide (HfO₂), zirconium oxide (ZrO₂), and aluminum oxide (Al₂O₃), or a stack structure thereof.

The charge storage layer 109A may be one of a nitride layer, e.g., a Si₃N₄ layer, or a dielectric layer capable of storing charges made of, e.g., a metal oxide such as hafnium oxide (HfO₂), zirconium oxide (ZrO₂), aluminum oxide (Al₂O₃), tantalum oxide (Ta₂O₃), and lanthanum oxide (La₂O₃), or a silicate such as hafnium silicon oxide (HfSiOₓ), zirconium silicon oxide (ZrSiₓ), and lanthanum silicon oxide (LaSiOₓ). The ‘x’ is a positive integer.

Also, in this embodiment, the nonvolatile memory device includes a gate electrode 111B formed over the upper insulation layer 110A. The gate electrode 111B may include an impurity-doped polycrystalline silicon layer, or a layer made of one of a transmission metal, a rare earth metal and an alloy thereof. Also, one of a metal nitride layer, a metal silicide layer, and a stack structure thereof can be formed over the gate electrode 111B to lower resistivity. The metal nitride layer may be formed of one of titanium nitride (TiN), tantalum nitride (TaN), and tungsten nitride (WN) layers. The metal silicide layer may be one of titanium silicide (TiSi₂) and tungsten silicide (WSiₓ) layers. The ‘x’ is a positive integer.

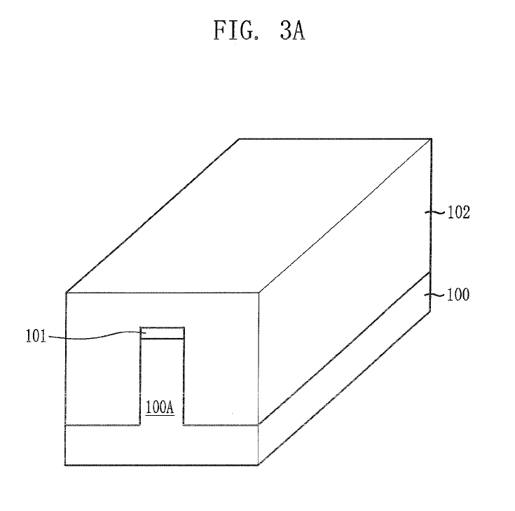

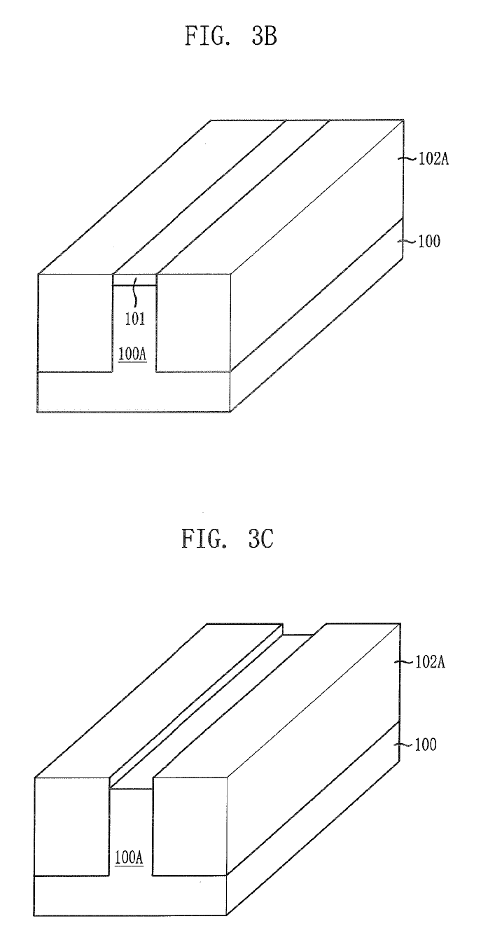

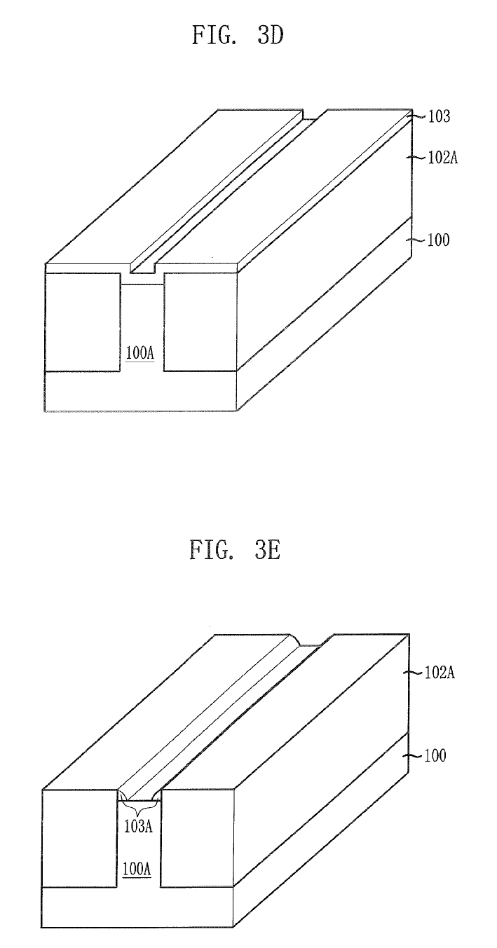

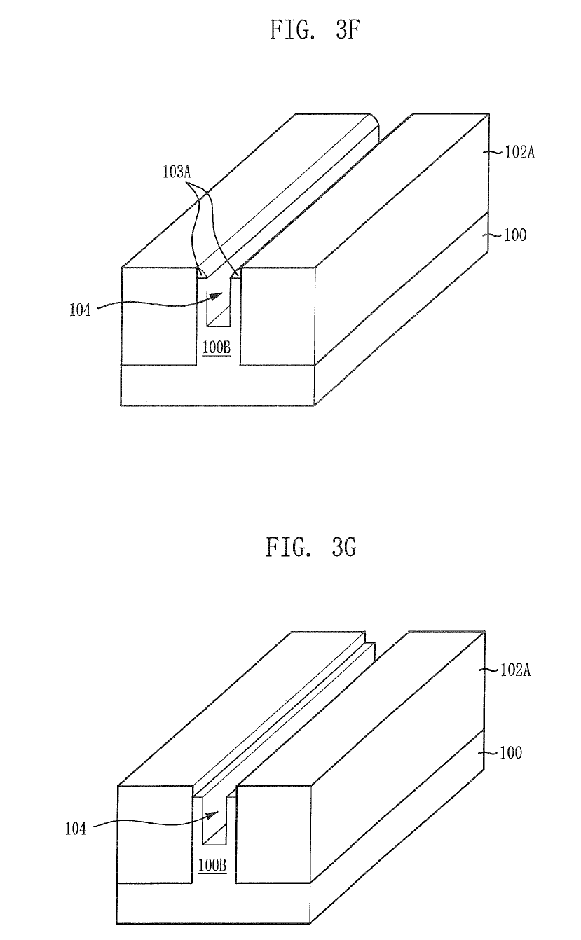

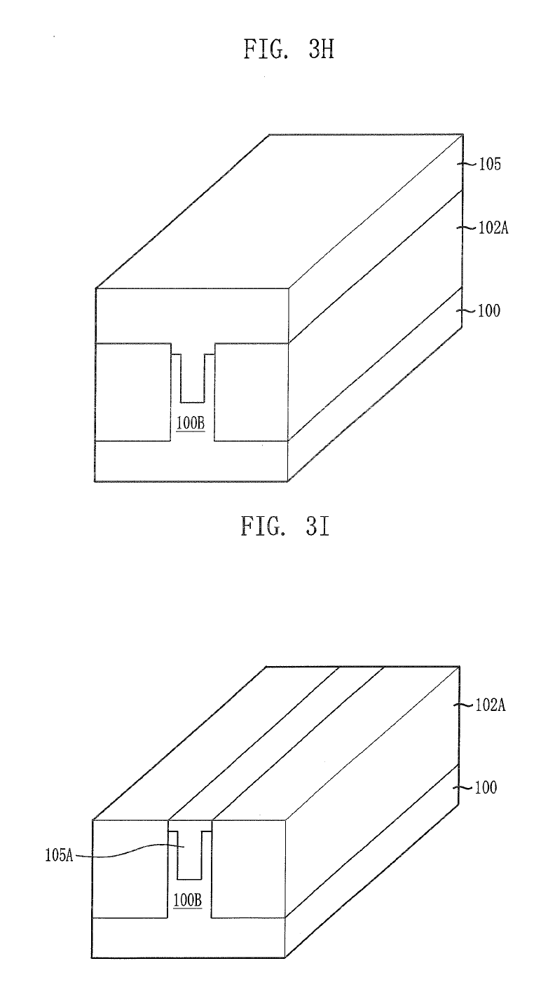

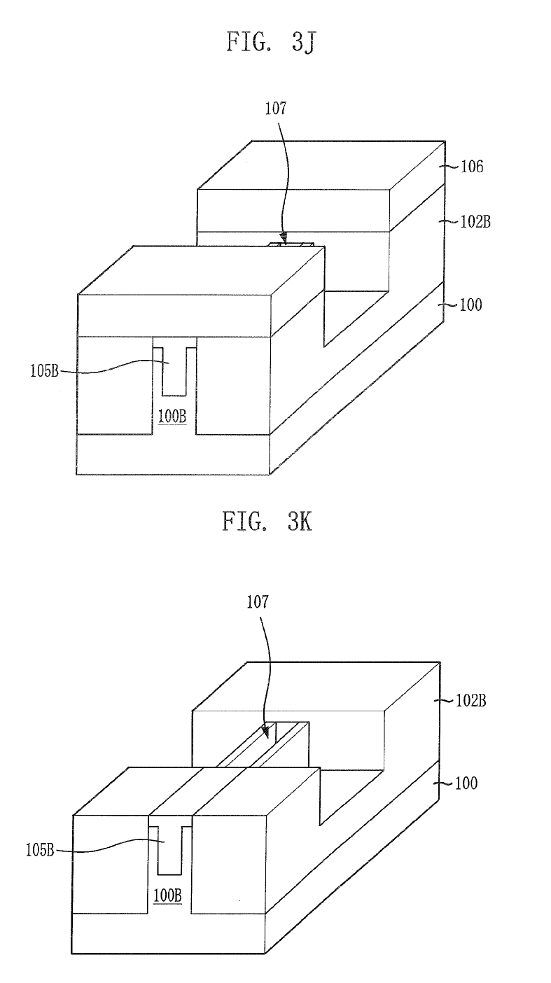

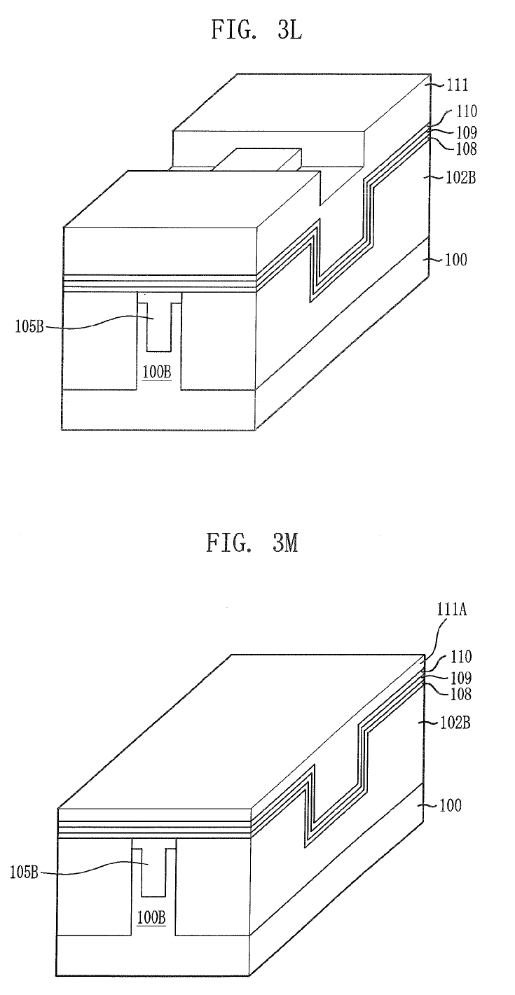

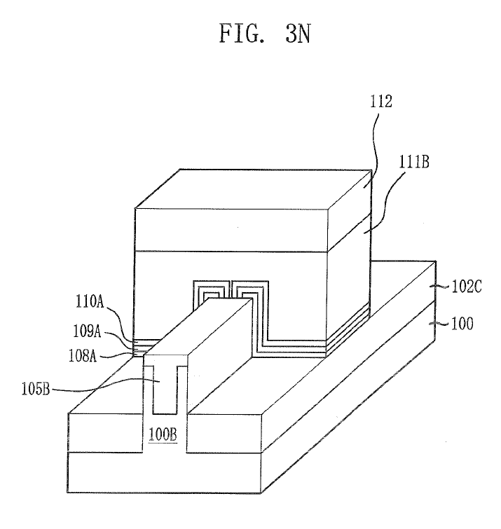

FIGS. 3A to 3N are perspective views of a method for fabricating the nonvolatile memory device in FIG. 1 according to the present invention.

Referring to FIG. 3A, a hard mask layer 101 is deposited on a substrate 100. The hard mask layer 101 is deposited by using a low pressure chemical vapor deposition (LPCVD) method to minimize a stress applied to the substrate 100 during a deposition process. Also, the hard mask layer 101 may be a nitride layer having high etch selectivity to the substrate 100, e.g., a silicon nitride (Si₃N₄) layer.

Also, before forming the hard mask layer 101, a buffer layer (not shown) can be formed over the substrate 100 to protect the substrate 100. The buffer layer may include a material having high etch selectivity to the hard mask layer 101. For instance, when the hard mask layer 101 is formed of a Si₃N₄ layer, the buffer layer can be formed of a SiO₂ layer. Also, the buffer layer is formed by an oxidation process using a dry-oxidation, a wet-oxidation, or a radical ion.

A trench (not shown) is formed by etching portions of the hard mask layer 101 and the substrate 100. Thus, a first active region 100A is defined in the substrate 100 as a line type.

An insulation layer 102 for isolation is deposited on the substrate 100 to fill the trench. The insulation layer 102 may be formed of a single layer or a stack structure in consideration of an aspect ratio. For instance, when the insulation layer 102 is formed of a single layer, a high density plasma (HDP) layer having a good filling characteristic to the high aspect ratio can be used. Other oxide-based layers having insulating properties also can be used, e.g., one of borophosphosilicate glass (BPSG), phosphosilicate glass (PSG), undoped silicate glass (USG), tetra ethyle ortho silicate (TEOS), borosilicate glass (BSG) layers, and a stack structure thereof. When the insulation layer 102 has a stack structure, it is preferable to sequentially stack the HDP layer, a spin on glass (SOG) layer, and the HDP layer. A polisilazane (PSZ) layer can be used as the SOG layer.

Referring to FIG. 3B, the isolation layer 102 is planarized to form an isolation pattern 102A having an upper surface aligned with the upper surface of the hard mask 101. At this time, a planarization process is performed by using a chemical mechanical polishing (CMP) or a blanket etch method, e.g., an etch-back process.

Referring to FIG. 3C, the hard mask layer 101 is removed to expose the first active region 100A. Phosphoric acid (H₃PO₄) solution can be used for the removal process.

Referring to FIG. 3D, an insulation layer 103 for a spacer is formed along the surface having a height difference over the substrate 100. The insulation layer 103 for the spacer may be a nitride layer having high etch selectivity to the isolation pattern 102A, e.g., a Si₃N₄ layer. The insulation layer 103 for the spacer may be formed of a SiO₂ layer. In this case, the spacer is formed on an inner wall of the isolation pattern 102A by controlling an etch time during the dry-etch process.

Referring to FIG. 3E, a blanket etch process, e.g., an etch-back process using a plasma etch system, is performed to etch the insulation layer 103 for the spacer. Thus, a spacer 103A is formed along the inner wall of the isolation pattern 102A on the upper portion of the first active region 100A.

Referring to FIG. 3F, an etch process using the spacer 103A as an etch barrier, e.g., the dry etch process, is performed to etch the first active region 100A to a certain depth to form a second active region 100B having a ‘U’ type or a ‘W’ type recess 104 with a certain depth.

Referring to FIG. 3G, the spacer 103A is removed. When the spacer 103A is a nitride layer, the spacer 103A can be removed by using the H₃PO₄ solution. When the spacer 103A is an oxide layer, one of diluted HF (DHF), buffered HF (BHF), and buffered oxide etchant (BOE) solutions can be used. When the H₃PO₄ solution is used, the second active region 100B of a Si layer can be seriously damaged. Accordingly, it is preferable to use a cleaning solution such as DHF, BHF and BOE solutions in order to minimize the damage of the second active region 100B and therefore, an oxide layer is preferable as the spacer 103A.

Referring to FIG. 3H, an insulation layer 105 is deposited on the substrate 100 to completely fill the recess 104 shown in FIG. 3G. The insulation layer 105 may be one of the HDP, SOG, BPSG, PSG, USG, BSG, TEOS layers, and a stack structure thereof.

Referring to FIG. 3I, the insulation layer 105 is planarized. The planarization process may be performed by the CMP or a blanket etch process, e.g., the etch-back process. Also, the planarization process is performed so that a portion of the insulation layer 105 remains over the active region 100B with a certain thickness as shown in FIG. 3I or with a top surface of the remaining insulation layer 105 being aligned with a top surface of projected wall portions of the second active region 100B. Hereinafter, the remaining insulation layer 105 after the planarization process will be referred to as an insulation pattern 105A.

Referring to FIG. 3J, a mask process including a photoresist coating, a photo-exposure, and a development process is performed to form a photoresist pattern 106, exposing a gate electrode formation region 107 where a gate electrode is to be formed.

Then, an etch process is performed using the photoresist pattern 106 as an etch mask to etch a portion of the isolation pattern 102A and a portion of the insulation pattern 105A, which is buried in the recess 104 (refer to FIG. 3G) in the gate electrode formation region 107. Thus, the recess 104 in the second active region 100B is exposed in the gate electrode formation region 107. As a result, a partially etched insulation pattern 105B and a partially etched insulation pattern 102B are formed.

Referring to FIG. 3K, the photoresist pattern 106 is removed. The photoresist pattern 106 can be removed by using an O₂ plasma in the plasma etch system.

Referring to FIG. 3L, a lower insulation layer 108, a charge storage layer 109, and an upper insulation layer 110 are sequentially deposited along a surface having height difference over the substrate 100.

The lower insulation layer 108A and the upper insulation layer 110A may be an oxide layer, e.g., a silicon oxide (SiO₂) layer or a high-k film having a dielectric coefficient higher than that of the SiO₂ layer, i.e., higher than approximately 3.9, which is made of one of metal oxide-based materials such as hafnium oxide (HfO₂), zirconium oxide (ZrO₂), and aluminum oxide (Al₂O₃), or a stack structure thereof. Furthermore, each of the lower insulation layer 108 and the upper insulation layer 110 may have a thickness of approximately 10 Å to approximately 100 Å.

The charge storage layer 109 may be one of a nitride layer, e.g., a Si₃N₄ layer, or a dielectric layer capable of storing charges made of, e.g., a metal oxide layer such as HfO₂, ZrO₂, Al₂O₃, Ta₂O₃, and La₂O₃, or a silicate layer such as HfSiOₓ, ZrSiₓ, and LaSiOₓ layers. The ‘x’ is a positive integer. Also, the charge storage layer 109 may be deposited to have a thickness of approximately 20 Å to approximately 500 Å by a chemical vapor deposition (CVD) or an atomic layer deposition (ALD) process.

A conductive layer 111 for a gate electrode is deposited on the upper insulation layer 110 subsequently. The conductive layer 111 may include a doped polycrystalline Si layer. Or, the conductive layer 111 may include one of a transmission metal and a rare earth metal, and an alloy thereof. For instance, the doped polycrystalline Si layer is deposited by using the LPCVD method during which a silane (SiH₄) gas is used as a source gas and a phosphine (PH₃) gas, a boron trichloride (BCl₃) gas, or a diborane (B₂H₆) gas is used as a doping gas. The transmission metal may include iron (Fe), cobalt (Co), tungsten (W), nickel (Ni), palladium (Pd), platinum (Pt), molybdenum (Mo), or titanium (Ti). The rare earth metal may include erbium (Er), ytterbium (Yb), samarium (Sm), yttrium (Y), lanthanum (La), cerium (Ce), terbium (Tb), dysprosium (Dy), holmium (Ho), thulium (Tm), or lutetium (Lu).

One of the metal nitride layer, the metal silicide layer, and a stack structure thereof can be formed over the conductive 111 to lower resistivity. For instance, the metal nitride layer may be a titanium nitride (TiN), a tantalum nitride (TaN), or a tungsten nitride (WN) layer. The metal silicide layer may be a titanium silicide (TiSi₂) layer or a tungsten silicide (Wsiₓ) layer. The ‘x’ is a positive integer.

Referring to FIG. 3M, the conductive layer 111 is planarized. The conductive layer 111 is planarized by using a CMP or an etch-back process. Hereinafter, the planarized conductive layer will be referred to as a planarized pattern 111A.

Referring to FIG. 3N, a photoresist pattern 112 covering the region for forming the gate electrode 111B (refer to FIG. 1) is formed by performing the mask process, which includes the photoresist coating, the photo-exposure, and the development processes.

The etch process is performed using the photoresist pattern 112 as an etch mask to form the gate electrode 111B. During the etch process, underlying layers are also etched to form a patterned insulation layer 108A, a patterned charge storage layer 109A, and a patterned upper insulation layer 110A. Then, the photoresist pattern 112 is removed.

The embodiments of the present invention are described using a silicon-oxide-nitride-oxide-silicon (SONOS) device as an example of a floating trap type memory device. However, this invention can also be applied to metal-nitride-oxide-semiconductor (MNOS), metal-alumina-oxide-semiconductor (MAOS), and metal-alumina-semiconductor (MAS) devices. Furthermore, it can be applied to a charge-trapping device including a flash memory device, e.g., a floating gate type memory device which is a field effect transistor (FET) storing a charge in an isolated conductive material, i.e., a floating gate.

Referring back to FIG. 3I, in the floating gate-type memory device, a tunneling insulation layer, a floating gate, and a dielectric layer are sequentially formed along the surface of the substrate 100 having height difference, instead of the lower insulation layer 108, the charge storage layer 109, and the upper insulation layer 11. The gate electrode 111B functions as a control gate.

According to the present invention, a recess is formed in an active region and sidewalls of the recess are exposed to increase a channel length and a channel width. Thus, although a gate dimension decreases due to high integration of a memory device, an effective channel width increases, thereby it is possible to secure an operation current.

While the present invention has been described with respect to the specific embodiments, it will be apparent to those skilled in the art that various changes and modifications may be made without departing from the spirit and scope of the invention as defined in the following claims.

What is claimed is:

1. A nonvolatile memory device, comprising:
an active region being defined by an isolation layer formed in a substrate and having a recess therein in a channel width direction, wherein an upper portion of the active region having the recess projects over an upper portion of the isolation layer;
a lower insulation layer formed along a surface of the active region and a top surface of the isolation layer;
a charge storage layer formed over the lower insulation layer;
an upper insulation layer formed over the charge storage layer; and
a gate electrode formed over the upper insulation layer.

2. A nonvolatile memory device, comprising:
an active region being defined by an isolation layer formed in a substrate and having a recess therein in a channel width direction, wherein an upper portion of the active region having the recess projects over an upper portion of the isolation layer;
a tunneling insulation layer formed along a surface of the active region and a top surface of the isolation layer;
a floating gate formed over the tunneling insulation layer;
a dielectric layer formed over the floating gate; and
a control gate formed over the dielectric layer.

3. The nonvolatile memory device of claim 1, wherein the recess is formed in a ‘U’ type or a ‘W’ type.

4. The nonvolatile memory device of claim 1, wherein the active region is defined as a line type or an island type in a channel length direction.

5. The nonvolatile memory device of claim 1, wherein the lower insulation layer is formed to contact with portions of an inner wall, a bottom portion of the recess, and an outer wall of the active region.

6. The nonvolatile memory device of claim 1, wherein the lower insulation layer and the upper insulation layer include one of a silicon oxide (SiO₂) layer, a layer having higher dielectric coefficient than that of the SiO₂ layer and a stack structure thereof.

7. The nonvolatile memory device of claim 1, wherein the charge storage layer includes a nitride layer or a metal oxide-based layer.

8. The nonvolatile memory device of claim 1, wherein the charge storage layer includes a silicate layer.

9. A method for fabricating a nonvolatile memory device, the method comprising:
forming an isolation layer to define an active region in a substrate;
forming a recess in the active region;
exposing inner and outer walls of the active region by removing a portion of the isolation layer;
forming a lower insulation layer along a surface of the active region and a top surface of the isolation layer;
forming a charge storage layer over the lower insulation layer;
forming an upper insulation layer over the charge storage layer; and
forming a gate electrode over the upper insulation layer.

10. A method for fabricating a nonvolatile memory device, the method comprising:
forming an isolation layer to define an active region in a substrate;
forming a recess in the active region;
exposing inner and outer walls of the active region by removing a portion of the isolation layer;
forming a tunneling insulation layer along a surface of the active region and a top surface of the isolation layer;
forming a floating gate over the tunneling insulation layer;
forming a dielectric layer over the floating gate; and
forming a control gate over the dielectric layer.

11. The method of claim 9, wherein forming the isolation layer comprises:
forming a hard mask layer over the substrate;
forming a trench by etching portions of the hard mask layer and the substrate; and
forming the isolation layer to fill the trench.

12. The method of claim 11, wherein forming the recess comprises:
removing the hard mask layer over the active region;
forming a spacer on an inner wall of the isolation layer over the active region;
etching the active region to form the recess using the spacer as an etch barrier; and
removing the spacer.

13. The method of claim 12, wherein the spacer includes a nitride layer or an oxide layer.

14. The method of claim 9, further comprising depositing an insulation layer to fill the recess before exposing the inner and outer walls of the active region.

15. The method of claim 14, wherein exposing the inner and outer walls of the active region exposes the outer walls of the active region by removing a portion of the isolation layer simultaneously with exposing inner walls of the active region by removing the insulation layer.

16. The method of claim 15, wherein the insulation layer is made of the same material as the isolation layer.

17. The method of claim 9, wherein the active region is formed in a line type or an island type.

18. The method of claim 9, wherein the isolation layer includes a high density plasma (HDP) layer or a stack structure of the HDP layer and a spin on glass (SOG) layer.

19. The method of claim 9, wherein the lower insulation layer and the upper insulation layer include one of a SiO₂ layer, a layer having higher coefficient than that of the SiO₂ layer and a stack structure thereof.

20. The method of claim 9, wherein the charge storage layer includes a nitride layer and a metal oxide-based layer.

21. The method of claim 9, wherein the charge storage layer includes a silicate layer.
